(19) United States
(12) Patent Application Publication
(10) Pub. No.: US 2009/0266395 A1
(43) Pub. Date: Oct. 29, 2009

(54) SOLAR CONCENTRATION AND COOLING DEVICES, ARRANGEMENTS AND METHODS

(75) Inventors: KRS Murthy, San Jose, CA (US); Robert S. Block, Reno, NV (US); Allen J. Amaro, Fremont, CA (US)

Correspondence Address: BUCHANAN, INGERSOLL & ROONEY PC, POST OFFICE BOX 1404, ALEXANDRIA, VA, 22313-1404, US

(73) Assignee: SUNRGI, Hollywood, CA (US)

(21) Appl. No.: 12/257,158

(22) Filed: Oct. 23, 2008

Related U.S. Application Data
(60) Provisional application No. 60/996,273, filed on Nov. 8, 2007.
(60) Provisional application No. 61/071,410, filed on Apr. 28, 2008.
(60) Provisional application No. 61/071,411, filed on Apr. 28, 2008.
(60) Provisional application No. 61/071,412, filed on Apr. 28, 2008.

(51) Int. Cl. H01L 37/00; H01L 31/00

(52) U.S. Cl. 136/206; 136/252

(57) ABSTRACT

Arrangements may include a concentrator constructed and arranged to receive incident electromagnetic energy and to concentrate the incident electromagnetic energy to a greater intensity level; an electromagnetic receiving device comprising a first surface constructed and arranged to receive the concentrated electromagnetic energy, and a second surface opposite the first surface; a heat transport device comprising at least one duct and a first surface; and a thermal interface layer physically connected to at least a portion of the second surface of the electromagnetic energy receiving device and the first surface of the heat transport device, the thermal interface material being both electrically and thermally conductive. Related methods and additional arrangements are also described.

This application claims the benefit, pursuant to 35 USC §119(e), of: U.S. Provisional Application No. 60/996,273 filed Nov. 8, 2007; U.S. Provisional Application No. 61/071,410 filed Apr. 28, 2008; U.S. Provisional Application No. 61/071,411 filed Apr. 28, 2008; and U.S. Provisional Application No. 61/071,412 filed Apr. 28, 2008. The entire contents of each of the aforementioned Applications is incorporated herein by reference, in its entirety.

### FIELD

The present invention relates to devices, arrangements and techniques for improved high-concentration conversion of electromagnetic energy, such as solar energy, to thermal energy and/or electricity with enhanced removal and/or transport of converted electromagnetic energy created at high concentration levels.

### BACKGROUND

In this specification where a document, act or item of knowledge is referred to or discussed, this reference or discussion is not an admission that the document, act or item of knowledge or any combination thereof was at the priority date, publicly available, known to the public, part of common general knowledge, or otherwise constitutes prior art under the applicable statutory provisions; or is known to be relevant to an attempt to solve any problem with which this specification is concerned.

Concentrating energy, such as solar energy, maximizes the ability to derive other forms of output therefrom. However, very high heat densities are often produced by sun concentrations of more than 1,000 times the nominal concentration of the sun's energy. This concentration is sometimes referred to as “1,000×” or “1,000 suns.” Some or all parts of an arrangement that are exposed to these levels of heat density may be destroyed or are rendered ineffective or inefficient. Consequently, at least some commercially available solar cells specify that they are not intended for use above 1,000 suns.

Moreover, conventional systems for achieving relatively high levels of solar concentration can require large and complex optical arrangements. Such arrangements often have a long focal length, and thus a large separation distance between the optics and the member receiving the concentrated solar energy. The size and complexity of such arrangements necessitates assembly of the various components in the field. Such assembly requires skill and precision, and adds to the overall cost of the system.

Therefore, it would be advantageous to provide improved structures, arrangements and techniques for cooling and heat transportation which have improved efficiency. In particular, it would be advantageous to provide such improvements in the areas of concentrated solar-thermal, photovoltaic and other concentrated solar electric power generation, as well as in other industries or applications such as the electronics industry. It would also be advantageous to provide adequate cooling under high solar concentration levels to prevent failure of concentrated solar systems and arrangements that may occur because of overheating. Finally, there is a need to provide concentrated solar-thermal, photovoltaic and other concentrated solar electric power generation arrangements with a simple, low-profile construction that enables rapid and cost-effective manufacture and assembly by mass-production techniques.

### SUMMARY

The present invention may provide devices, arrangements, systems, and methods for improved heat transport, extraction, cooling, storage and management.

The principles and embodiments of the present invention can be utilized in conjunction with solar thermal, photovoltaic and other solar electric power generation applications.

The present invention may include devices, arrangements, and methods that generate very high heat densities. Such devices, arrangements and methods may include high heat densities produced by high sun concentration levels, such as 10× or more, 1,000× or more, 1,600× or more, 1,800× or more, 2,000× or more, or 10,000× or more.

According to one aspect, the present invention provides devices, arrangements and techniques that produce highly concentrated solar energy and directs that energy onto one or more solar cell, resulting in efficient energy conversion with fewer solar cells than an arrangement that lacks such high concentration levels. Thus, the present invention provides effective electrical power generation with a relatively lower cost per unit area.

According to a further optional aspect, the present invention provides efficient cooling or transporting of heat away from one or more solar cell, resulting in higher energy conversion efficiency. Thus, higher solar concentrations combined with efficient cooling or heat transport provides higher electrical power output per unit area of the solar cell, or solar cell array.

According to an additional aspect, the present invention provides an arrangement constructed to provide the above-mentioned performance benefits, while having a relatively low-profile form factor. The present invention can also provide a construction an arrangement which is suitable for manufacture by mass-production techniques, as opposed to relatively costly and laborious field assembly.

According to the present invention there is provided an arrangement comprising: a concentrator constructed and arranged to receive incident electromagnetic energy and to concentrate the incident electromagnetic energy to a greater intensity level; an electromagnetic energy receiving device comprising a first surface constructed and arranged to receive the concentrated electromagnetic energy, and a second surface opposite the first surface; at least one optical relocator constructed and arranged to re-direct concentrated electromagnetic energy onto at least a portion of the first surface; a heat transport device comprising at least one duct and a first surface; and a thermal interface layer physically connected to at least a portion of the second surface of the electromagnetic energy receiving device and the first surface of the heat transport device, the thermal interface material being thermally conductive, electrically conductive, or both.

According to a further aspect, the present invention provides an arrangement comprising: a photovoltaic solar cell comprising a first surface for receiving concentrated solar energy incident thereon, and a second opposing surface; a heat transport device comprising a first surface; and a thermal interface layer physically connected to the second surface of the solar cell and the first surface of the heat transport device, the thermal interface material being electrically and/or thermally conductive; wherein the arrangement converts the concentrated solar energy to at least 37 Watts of DC electricity/cm² of photovoltaic cell area.

According to a another aspect, there is provided an array comprising: at least one concentrator, the at least one concentrator constructed and arranged to receive incident electromagnetic energy and to concentrate the incident electromagnetic energy to a greater intensity level; a plurality of electromagnetic energy receiving devices, each device comprising a first surface constructed and arranged to receive concentrated electromagnetic energy, and a second surface opposite the first surface; at least one optical relocator constructed and arranged to re-direct concentrated electromagnetic energy onto at least a portion of the first surface; at least one heat transport device comprising a first surface; and a thermal interface layer physically connected to at least a portion of the second surface of the electromagnetic energy receiving device and the first surface of the heat transport device, the thermal interface material being thermally conductive, electrically conductive, or both.

According to an additional aspect, the present invention provides an arrangement comprising: at least one concentrator constructed and arranged to receive incident electromagnetic energy and to concentrate the incident electromagnetic energy to a greater intensity level; at least one electromagnetic energy receiving device comprising a first surface constructed and arranged to receive the concentrated electromagnetic energy; a heat transport device in thermal communication with the at least one electromagnetic energy receiving device; and at least one optical relocator constructed and arranged to re-direct concentrated electromagnetic energy onto at least a portion of the first surface.

According to still another aspect, the present invention provides an arrangement comprising a circuit board comprising an upper electrically insulating layer having an opening disposed therein; an electromagnetic energy receiving device comprising a first surface having an active area and a second opposing surface, the active area in communication with the opening in the insulating layer; and a relocator comprising a member, the member comprising a first opening, a second opening, and converging side surfaces connecting the first and second openings, the side surface converging toward the second opening, the second opening disposed for direct communication with the opening in the insulating layer; wherein electromagnetic energy incident upon the relocator is directed onto the active area of the electromagnetic energy receiving device.

According to another additional aspect, the present invention provides an arrangement comprising a circuit board; and an array of solar cells disposed on the circuit board; wherein the solar cells of the array are electrically connected to at least one of the protection diodes, blocking diodes, or bypass diodes, in either a series or parallel relationship so as to provide a desired voltage and current combination.

According to an additional aspect, the present invention provides an arrangement comprising a circuit board comprising an upper electrically insulating layer having an opening disposed therein; an electromagnetic energy receiving device comprising a first surface having an active area and a second opposing surface, the active area in communication with the opening; an electrical contact area in electrical communication with the active area; an optical relocator comprising a member, the member comprising a first opening, a second opening, and converging side surfaces connecting the first and second openings, the side surfaces converging toward the second opening, and the second opening disposed for direct communication with the opening in the upper insulating layer; wherein electromagnetic energy incident upon the relocator is directed onto the active area of the electromagnetic energy receiving device.

### BRIEF DESCRIPTION OF THE DRAWINGS

FIG. 1 is a schematic illustration of an arrangement formed according to one aspect of the present invention.

FIG. 2 is a schematic illustration of a modified arrangement formed according to the principles of the present invention.

FIG. 3 is schematic illustration of the arrangement of FIG. 2 oriented at a second position corresponding to the movement of a source of electromagnetic energy.

FIG. 4 is a top plan view of a tracking arrangement formed according to one embodiment of the present invention.

FIG. 5 is a side plan view of the arrangement of FIG. 4.

FIG. 6 is a side view of an arrangement formed according to a further aspect of the present invention.

FIG. 7 is an end of view of the arrangement of FIG. 6.

FIG. 8 is a perspective view of the arrangement of FIG. 6.

FIG. 9 is an end of view of the arrangement of FIG. 8.

FIG. 10 is a side partial cutaway view of an arrangement and cooling configuration formed according to another embodiment of the present invention.

FIG. 11 is a perspective view of an arrangement formed according to a further embodiment of the present invention.

FIG. 12 is a perspective view of an arrangement formed according to another aspect of the present invention with an additional option feature illustrated.

FIG. 13 is an exploded perspective view of an arrangement formed according to an additional embodiment of the present invention.

FIG. 14 is a sectional view taken along line A-A of FIG. 13 with additional optional features illustrated.

FIG. 15 is a partial perspective view of an alternative embodiment of a component of the arrangement of FIGS. 13-14.

FIG. 16 is a perspective view of an arrangement similar to the arrangement of FIGS. 13-14.

FIG. 17 is a cross-sectional view of an arrangement formed according to a further aspect of the present invention.

FIGS. 18-18A are top and cross-sectional views, respectively, of an optical relocator formed according to an alternative embodiment of the present invention.

FIG. 19 is a cross-sectional view of an optical relocator formed according to a further alternative embodiment of the present invention.

FIG. 20 is a perspective view of an optical relocator formed according to an additional alternative embodiment of the present invention.

FIG. 21 is a top view of an arrangement formed according to a further embodiment of the present invention.

FIG. 22 is a perspective view of an alternative arrangement.

FIG. 23 is a perspective view of the arrangement of FIG. 21.

FIG. 24 is a side view of the arrangement of FIG. 23.

FIG. 25 is a side view of an arrangement of the present invention.

FIG. 26 is a perspective schematic view of arrangements formed according to the present invention.

### DEFINITIONS

Unless otherwise defined herein or in the remainder of the specification, all technical and scientific terms used herein have meanings commonly understood by those of ordinary skill in the art to which the present invention pertains.

Before describing the present invention in detail, it is to be understood that the terminology used in the specification is for the purpose of describing particular embodiments, and is not necessarily intended to be limiting. As used in this specification and the appended claims, the singular forms “a”, “an” and “the” do not preclude plural referents, unless the context clearly dictates otherwise. It is to be understood that reference herein to first, second, third and fourth components (etc.) does not limit the present invention to embodiments where each of these components is physically separable from one another. For example, a single physical element of the invention may perform the features of more than one of the claimed first, second, third or fourth components. Conversely, a plurality of separate physical elements working together may perform the claimed features of one of the claimed first, second, third or fourth components. Similarly, reference to first, second (etc.) method steps does not limit the invention to only separate steps. According to the invention, a single method step may satisfy multiple steps described herein. Conversely, a plurality of method steps could, in combination, constitute a single method step recited herein. In addition, the steps are not necessarily limited to the order in which they are set forth herein.

As used herein, the term “electromagnetic energy receiving device” means one or more devices arranged for receiving one or more forms of electromagnetic energy, such as solar energy, infrared energy, far infrared energy, microwave energy, sound energy, phonon energy, or radio waves, and converting the electromagnetic energy incident thereon to one or more forms of energy which differ than the form which is incident thereon. The converted energy may take the form of electrical current, heat, mechanical energy and/or fluid pressure. Such electromagnetic energy receiving devices include, but are not limited to, photovoltaic solar cells and passive solar thermal receptors.

As used herein, the term “heat transfer media” means a vapor, a single fluid, mixed fluids, or multiphase fluids. The heat transfer media may have any suitable pressure, including pressures equal to, less than, or higher than, atmospheric pressure. The heat transfer media may include, but is not limited to, one or a combination of: organic fluid, inorganic fluid, biological fluid, water, steam, oil, solid particles or structures of organic, inorganic or biological materials, and various sizes of particles or structures having micro- or nano-sized dimensions, including but not limited to tetrapods and millipods. When present in the form of a mixture, the heat transfer media may take the form of a colloidal dispersion or emulsion.

As used herein, the term “duct” shall mean one or more structures capable of containing or conducting the heat transfer media therethrough. The duct includes structures such as channels, canals, tubes, conduits, passageways, tubules and capillaries. The duct may be open or closed. The term “duct” is not limited to any particular material, cross-sectional geometry or dimension. For purposes of illustration, the duct can be provided with dimensions on the order of 1 nm to 10 cm.

### DETAILED DESCRIPTION

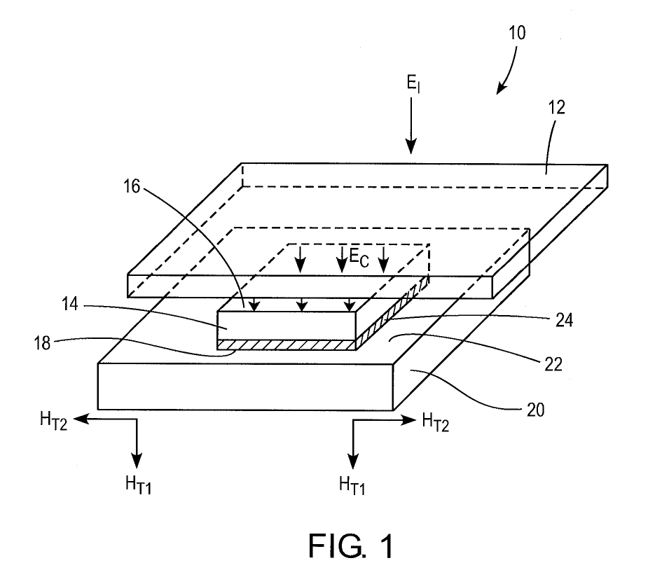

An exemplary arrangement formed according to the principles of the present invention is illustrated in FIG. 1. As illustrated therein, the arrangement 10 includes a concentrator 12. The concentrator 12 receives incident electromagnetic energy E_{I} and transmits a concentrated form of electromagnetic energy E_{C}. According to certain embodiments, the transmitted energy E_{C} is concentrated. It is contemplated that the level of concentration may vary widely between 10×-10,000×. For instance, the concentration level may be 1000× or more, 1600× or more, 1800× or more, or 2000× or more, relative to the intensity of the incident electromagnetic energy E_{I}. The concentrator 12 can take any suitable form which produces the above-mentioned concentration function. For example, the concentrator 12 can comprise one or more optical elements. Suitable optical elements may include one or more of a reflective element, a refractive element or a holographic element. According to one illustrative example, the optical element comprises a Fresnel lens. The concentrator 12 can be formed from any suitable optical material. According to non-limiting examples, the concentrator 12 can be formed from an optical material such as one or more of plastic, acrylic material, quartz, glass, metal, semiconductor material, films and fluid-filled structures. The concentrator 12 can be planar or curved.

The arrangement 10 further comprises at least one electromagnetic energy receiving device 14. The electromagnetic energy receiving device 14 comprises a first surface 16 for receiving the concentrated electromagnetic energy E_{C} thereon, and a second surface 18, opposite the first surface 16. The electromagnetic energy receiving device 14 can take any suitable form. For example, according to certain illustrative embodiments, the electromagnetic energy receiving device 14 can comprise one or more photovoltaic solar cell, or one or more thermal receptors. A thermal receptor receives the electromagnetic energy E_{C} and converts it, primarily to thermal energy, which can in turn be captured in utilized for performing useful work such as heating water. Heated water can of course be used for number of different useful purposes, including powering steam turbines for generating electricity.

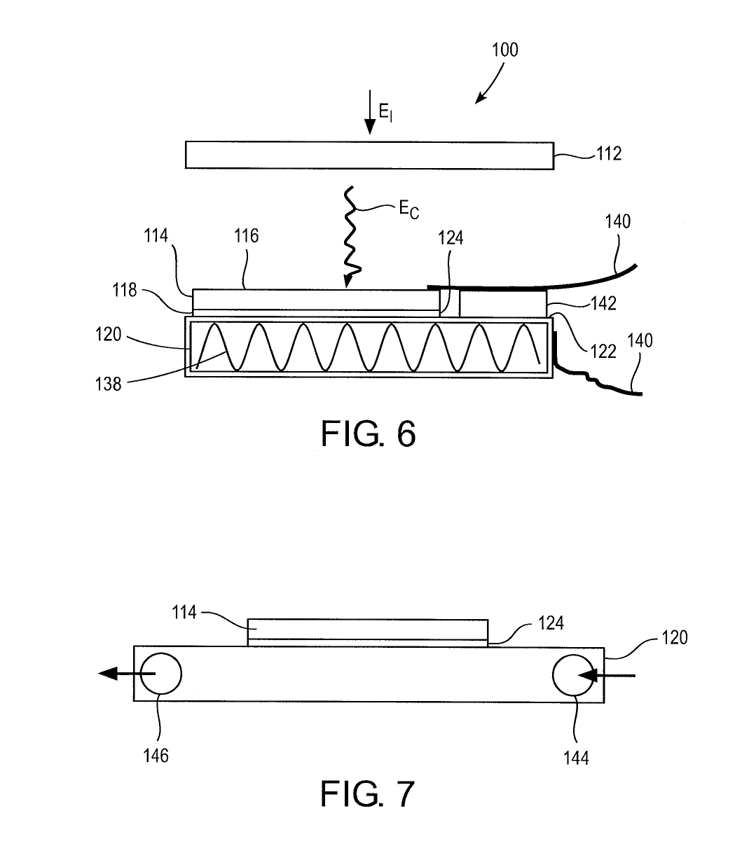

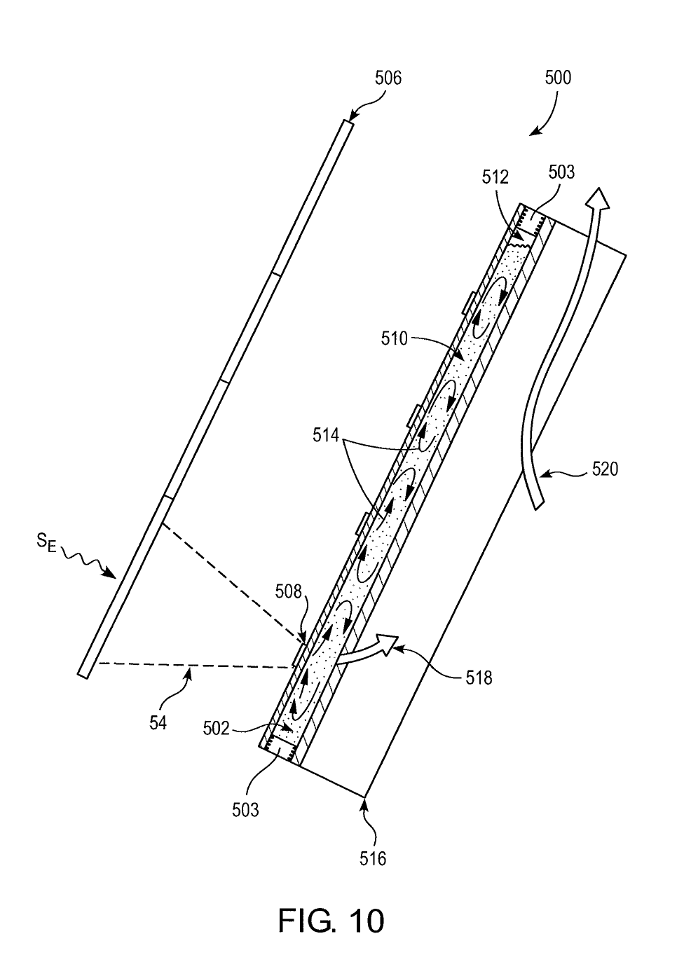

According to the illustrative embodiment of FIG. 1, the arrangement 10 further includes at least one heat transport device 20. The at least one heat transport device 20, preferably transports thermal energy in at least one of the general directions indicated by arrows H_{T1}, H_{T2}. The heat transport device 20 can take any suitable form capable of performing the above-mentioned thermal energy transfer. The heat transport device 20 can implement either passive or active cooling techniques. Thus, for example, a heat transfer media can be circulated within the heat transport device 20 (e.g., FIG. 7), thereby forming an active cooling system. Alternatively, the heat transport device 20 can form a closed system containing a heat transfer media therein (e.g., FIG. 10). The heat transport device 20 may optionally comprise at least one duct therein (e.g., FIG. 6). Heat transfer media may be circulated within the heat transport device 20, at least partially within the at least one optional duct.

According to yet another alternative, the heat transport device 20 may omit the heat transfer media, and simply radiate heat to the surrounding environment via any number of known configurations, such as external fins (see, e.g., FIGS. 10, 12, 13 and 15) and the like. The heat transport device 20 can be formed of any suitable material, preferably a material that has a high thermal conductivity. Thus, for example, the heat transport device 20 can be formed from a metal or metal alloy having a high thermal conductivity. Non-limiting examples include one or more of: aluminum, aluminum alloys, copper and copper alloys. Alternatively, the heat transport device 20 may be formed, at least in part, from a designer composite material as described in copending provisional U.S. Patent Application No. 61/071,412 entitled “Composite Material Compositions, Arrangements and Methods Having Enhanced Thermal Conductivity Behavior,” and non-provisional U.S. patent application Ser. No. ______ having the same title filed on an even date herewith, the entire contents of which is incorporated herein by reference. The heat transport device 20 may also comprise a first surface 22.

The arrangement 10 may further include a thermal interface layer 24 physically connected to at least a portion of the second surface 18 of the electromagnetic energy receiving device 14, and to at least a portion of the first surface 22 of the heat transport device 20. According to certain aspects, there are no other intervening layers, components, or materials between the second surface 18 of the electromagnetic energy receiving device 14, the thermal interface layer 24, and the first surface 22 of the heat transport device 20. The thermal interface layer 24 preferably possesses high thermal conductivity. The thermal interface layer 24 optionally possesses high electrical conductivity as well. For example, the thermal interface layer 24 can have a thermal conductivity of 1 W/m*K up to 10,000 W/m*K, and optionally may have an electrical conductivity of 10 siemens to 10 micro-siemens, or more. The thermal interface layer 24 can be formed from any suitable material possessing the above-mentioned high thermal conductivity and high electrical conductivity. The thermal interface layer can be formed from one or more layers of a matrix of one or more combination(s) of a variety of multiphase material, with phase changing properties. According to nonlimiting examples, the thermal interface layer may comprise one or more of: a silver alloy, tin-indium alloy, tin-bismuth alloy, lead-free solder, liquid metal, liquid metal alloy, organic material inorganic material, thermal grease, solder, polymer, various sizes of structures in micro, nano or other dimensions including tetrapods and millipods, and films of a variety of thicknesses, being at least thermally conductive to ensure an efficient heat transport path, which also may include electrical conductivity provided through the same or an alternate path, or portion of the path, as the thermal transport path. According to a further alternative embodiment, the thermal interface layer 24 can be formed from the designer composite material as described in copending provisional and non-provisional U.S. patent application Nos. 61/071,412 and ______ entitled “Composite Material Compositions, Arrangements and Methods Having Enhanced Thermal Conductivity Behavior.”

The thermal interface layer 24 can be provided with any suitable thickness, pattern, or geometry. According to one illustrative example, the thermal interface layer 24 comprises a relatively continuous layer that is 10 nm-5 mm in thickness having an area corresponding to the entire area of the second surface 18 of the electromagnetic energy receiving device 14.

When embodied in the context of a photovoltaic device or arrangement, the present invention is particularly effective or efficient in converting incident solar energy E_{I} into electricity. For example, arrangements formed as described herein and according to the principles of the present invention are expected to produce electricity on the order of up to 400 W/m² of photovoltaic system area, or more.

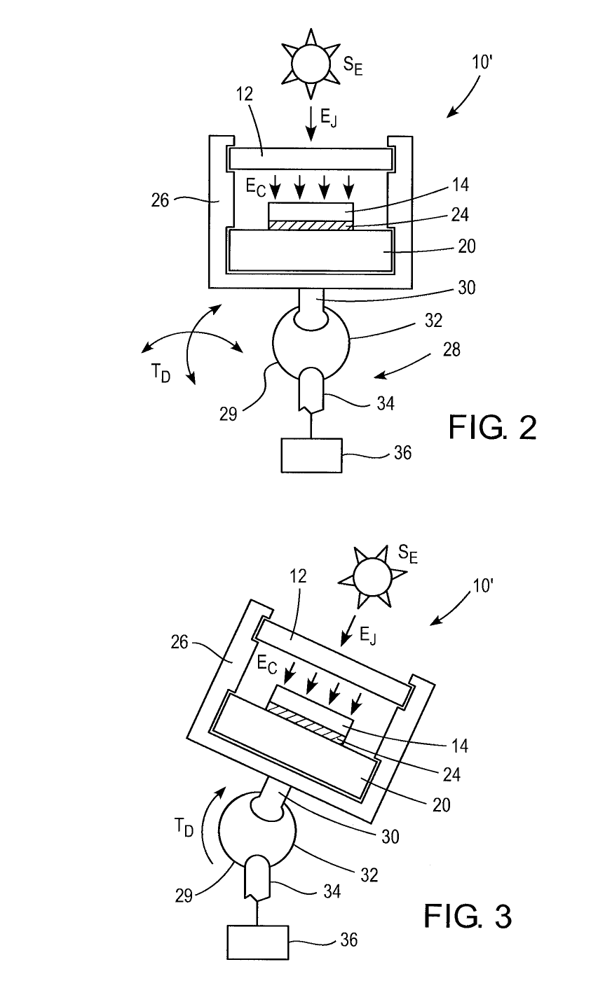

According to an additional embodiment of the present invention, an alternative arrangement 10′ formed according to the principles of the present invention is illustrated in FIGS. 2-3. The arrangement 10′ shares many of the features described above in connection with the arrangement 10. Thus, the same reference numerals used in connection with the description of the arrangement 10 have been used to indicate corresponding features appearing in arrangement 10′. Unless otherwise indicated herein, the features of the arrangement 10′ which are common to the features of arrangement 10 possess any and all of the characteristics described above, and are incorporated into this description of arrangement 10′ by reference. Thus, the description of these common features will not be repeated. Generally, the arrangement 10′ adds a tracking mechanism to the above described arrangement 10 which enables the arrangement to follow movement of a source of electromagnetic energy S_{E}.

The assembly 10′ is illustrated at a first position in FIG. 2, and includes a frame 26 which holds the concentrator 12, electromagnetic energy receiving device 14, heat transport device 20, and thermal interface layer 24 in an operable position relative to one another. The frame 26 may be connected to a tracking assembly or device 28. Any suitable tracking assembly 28 is comprehended for use in conjunction with the arrangement 10′. Suitable tracking assemblies may include a variety of two-axis tracking assemblies and/or three-axis tilting/tracking assemblies. According to one embodiment, as illustrated in FIGS. 2-3, a tracking assembly 28 is connected to the frame 26 via a first connector 30. The first connector 30 is operatively associated with an articulating joint 29. A second connector 34 is also operatively associated with the articulating joint 29. According to the illustrated embodiment, this construction of the tracking assembly 28 enables translation of the arrangement 10′ in at least the directions indicated by arrows TD. The second connector 34 may be operatively associated with a drive mechanism 36. The drive mechanism 36 can take any suitable form. For example, the drive mechanism 36 can comprise one or more motors, gearing, linear drives, mechanical means, electromechanical means, servo devices and the like. The drive mechanism may also include one or more controllers, which may comprise a microprocessor, sensor(s), and other suitable electronic components. Thus, as illustrated in FIG. 3, the arrangement 10′ is able to adjust or track according to the position of the source of electromagnetic energy S_{E}, thereby optimizing the angle and amount of electromagnetic energy incident upon the assembly.

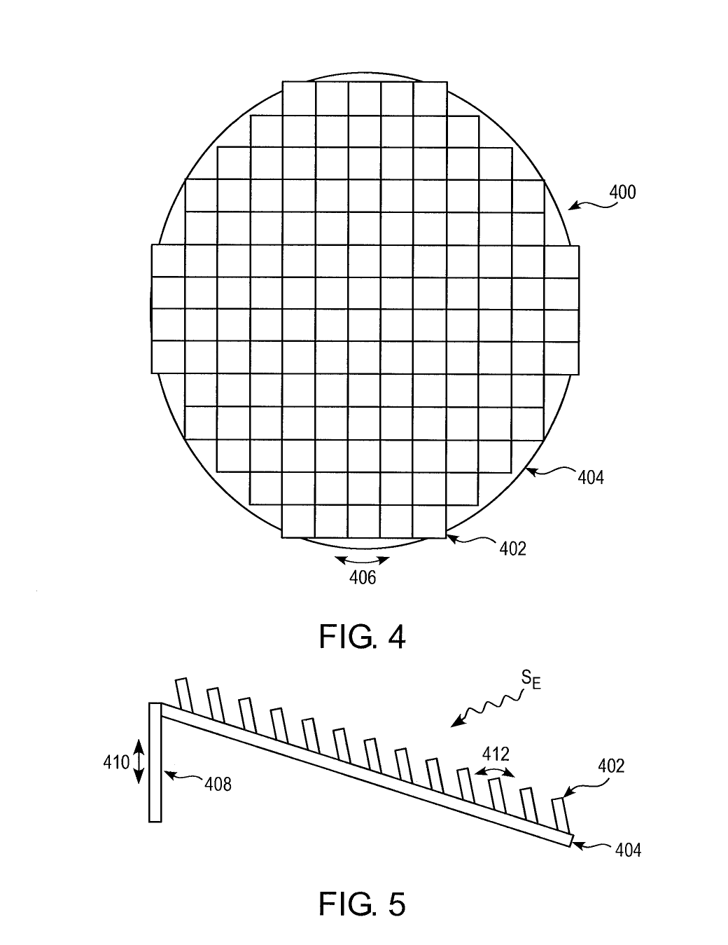

A tracking system or assembly formed according to a further alternative embodiment which can be utilized in connection with the devices and arrangements of the present invention is illustrated in FIGS. 4-5. The arrangement illustrated therein comprises an array 400 containing a plurality of compact highly concentrated solar photovoltaic system modules 402. Each of the modules 402 can have any of the features described herein as being associated with arrangement 10, or subsequent embodiments thereof. The array can be in the form of a one or two dimensional array. Thus, for example, the array 400 may be planar or curved in overall configuration. The array 400 may comprise a support structure 404. However, it should be understood that the array 400 and its support structure 404 are not limited to the illustrated circular geometry. The support structure 404 has the ability to rotate as indicated by arrow 406 via a motion control system that tracks the periodic movement of the source of solar or electromagnetic energy S_{E}. Component 408 is designed to provide seasonal tracking adjustment, as indicated by arrow 410. In addition, finer adjustments, such as the tilt motion as indicated by arrow 412, may also be performed so as to accurately track the source of electromagnetic energy S_{E}.

An arrangement constructed according to a further optional embodiment of the present invention is illustrated in FIGS. 6-9. An exemplary arrangement 100 is illustrated therein. The arrangement 100 includes a concentrator 112. The concentrator 112 receives incident solar energy E_{I} and transmits a concentrated form of solar energy E_{C}. Thus, according to certain embodiments, the transmitted energy E_{C} is concentrated. It is contemplated that the level of concentration may vary widely between 10×-10,000×. For instance, the concentration level may be 1000× or more, 1600× or more, 1800× or more, or 2000× or more, relative to the intensity of the incident electromagnetic energy E_{I}. The concentrator 112 can take any suitable form which produces the above-mentioned concentration function. For example, the concentrator 112 can comprise one or more optical elements of the type described previously herein. One suitable optical element comprises a Fresnel lens. A Fresnel lens may have any suitable construction, as previously described herein. The concentrator 112 can be formed from any suitable optical material, as also described in connection with previous the concentrator 12.

The arrangement 100 may further comprise at least one electromagnetic energy receiving device, such as at least one photovoltaic solar cell 114. Any suitable photovoltaic solar cell can be used in conjunction with the arrangement 100. The photovoltaic solar cell 114 may comprise conventional electronic packaging components associated therewith. Alternatively, a photovoltaic solar cell 114 may have any such electronic packaging components removed therefrom, as is the case with the embodiment illustrated in FIGS. 6-9. The at least one photovoltaic solar cell 114 can possess any suitable size or geometry. According to nonlimiting examples, the at least one photovoltaic solar cell 114 has one or more dimensions of its active area of 1 nm-1000 mm. Thus, the active area can range from 1 nm² to 1,000 mm². For example, the cell may have an active area that is 100 square cm, 1 square cm, 1 square mm, 4 square mm or 300 square mm. The active area can be of any suitable geometry, such as a polygon, oval or circle. The area may be wafer-like in size, proportions and/or shape. According to a further optional embodiment, the assembly 100 comprises one, and only one, photovoltaic solar cell 114. Alternatively, a plurality of solar cells 114 may be provided.

The photovoltaic solar cell 114 comprises a first surface 116 for receiving the concentrated solar energy E_{C} thereon, and a second surface 118, opposite the first surface 116. According to certain embodiments, the arrangement 100 may include electrical contacts or connectors 140 which provide electrical communication between the least one photovoltaic solar cell 140 and another component of the arrangement, such as a printed circuit board 142.

According to the illustrative embodiment, the arrangement 100 further includes at least one heat transport device 120. The at least one heat transport device 120, preferably transports thermal energy away from the at least one photovoltaic solar cell 114. The heat transport device 120 can take any suitable form capable of performing the above-mentioned thermal energy transfer. The heat transport device 120 can implement either passive or active cooling techniques. Thus, for example, a heat transfer media can be circulated within the heat transport device 120 via at least one inlet 144 and at least one outlet 146, thereby forming an active cooling system. The heated media, once removed through the outlet 146 may optionally be circulated through a heat transfer device, such as a radiator (not shown), and returned via the inlet 144. The heat transport device 120 may optionally comprise at least one duct 138 therein. Heat transfer media may be circulated within the heat transport device 120, at least partially through the at least one duct 138. Alternatively, the heat transport device 120 can define a closed system containing a heat transfer media therein.

According to yet another alternative, the heat transport device may omit the heat transfer media, and simply radiate heat to the surrounding environment via any number of known configurations, such as external fins and the like.

The heat transport device 120 can be formed of any suitable material, preferably a material that has a high thermal conductivity value. Thus, the heat transport device 120 can be formed from any of the material described above in connection with heat transport device 20. The heat transport device 120 may also comprise a first surface 122.

The arrangement 100 may further include a thermal interface layer 124 physically connected to at least a portion of the second surface 118 of the at least one photovoltaic solar cell 114, and to at least a portion of the first surface 122 of the heat transport device 120. According to certain aspects, there are no other intervening layers, components, or materials between the second surface 118 of the electromagnetic energy receiving device 114, the thermal interface layer 124, and the first surface 122 of the heat transport device 120. The thermal interface layer 124 preferably possesses high thermal conductivity. The thermal interface layer 124 may optionally possess high electrical conductivity, and may possess any of the thermal and/or electrical performance capabilities discussed herein in connection with thermal interface layer 24. The thermal interface layer 124 can be formed from any suitable material discussed above in connection with thermal interface layer 24. The thermal interface layer 124 can be provided with any suitable thickness, pattern, or geometry. According to one illustrative example, the thermal interface layer 124 comprises a layer having a thickness of 10 nm-5 mm that is a continuous layer having an area corresponding to the entire area of the second surface 118 of the electromagnetic energy receiving device 114.

Mounting the at least one photovoltaic solar cell 114 directly on the heat transport device 120, without the typical ceramic substrate solar cell packaging, enables maximum heat transfer from the solar cell to the heat transport device 120. In addition, since the thermal interface layer 124 and the heat transport device 120 can both be electrically conductive, the entire second surface 118 of the solar cell 114 can form a main electrical contact or electrode. Making the heat transport device 120 as one leg of an electrical circuit provides an opportunity to enhance the cooling capability. While not wishing to be bound to any particular theory, improved cooling is believed to result from the following phenomenon. First, direct thermal phonon coupling (material lattice vibration) of the solar cell in contact with the heat transport device. Second, the direct flow of heat energy carrying free electrons from the solar-cell to the cool the heat transport device because the heat transport device is part of the electrical circuit (electron-electron energy transfer is faster in transferring energy to induce progressive local lattice vibration which is slower). When the solar-cell converts the sun's electromagnetic radiation into electrons, the electrons carry away approximately 20% of the heat energy lowering the temperature an additional 20%. This energy is no longer heating the cell. This extra cooling was measured directly during experiments. Third, solar-cell packaging substrate is typically germanium, which is transparent to the longer wavelengths of the solar energy. These longer wavelengths cannot be utilized by the cell to convert to electricity and end up as heat. The invention provides a direct path for the longer wavelengths to pass through the solar cell to the cool heat transport device without heating the cell. Heat from the cells is quickly moved away from the junction with the heat transport device.

Alternatively, the present invention can be combined directly with conventional solar cell arrangements that include their standard ceramic substrate and/or mounting and still provide advantages and benefits due to the exceptional cooling and heat transport properties.

The electromagnetic energy receiving device(s) collect energy. This energy can be put to one or more primary uses: generating electric current directly from the incident energy and/or heating a working fluid or a heath transfer media, such as water. The heated working fluid or heat transfer media can optionally be used to produce electricity as well, such as by using it to drive turbines and the like.

Where the electromagnetic energy receiving device is a photovoltaic solar cell, the heat transport device can serve to transport heat away from the solar cell to keep the solar cell cool. Since the energy conversion efficiency of the cell is reduced for every degree centigrade of temperature increase above 25° C., by transporting heat away from the solar cell the cell maintains its efficiency in converting solar energy to electricity.

Depending on the application and customer requirements, it may be valuable to compromise on the electrical conversion efficiency by reducing/regulating the heat transfer media flow through and around the cells and cell package to collect more heat per unit of heat transfer media flow rate. For example, hot water can be produced for utility applications. For every degree increase in cell junction temperature achieved by reduced water flow rate and some recirculation of the water, there is a compromise in the electrical conversion efficiency, yet on the other hand, a gain in increased temperature of the water coming out of each cell.

Very high thermal conductivity composites and thin films can be used in cooling and heat transfer to efficiently move the heat from the junction of the solar cells to the heat transport device. Efficient thermal transfer coupling techniques are used to transfer heat from the conductive part to the convective part of the system.

An illustrative non-limiting embodiment of an arrangement including closed-type cooling construction is illustrated in FIG. 10. As illustrated therein, the arrangement 500 includes a closed chamber 502. The chamber 502 may be closed by any suitable means. Thus, for example, the chamber 502 may be closed by removable plugs 503. As illustrated in FIG. 10, the arrangement 500 may be implemented in a non-horizontal manner, such as a generally vertically-oriented incline. The angle of inclination of the arrangement 500 should be suitable for receiving a source of electromagnetic or solar energy S_{E}. The electromagnetic or solar energy is focused and optionally concentrated by optical element 506, and directed onto one or more electromagnetic energy receiving devices or photovoltaic solar cells 508. The optical element 506 may have any suitable construction, such as the constructions of the optical elements/lenses as described in the embodiments contained herein. When the incident electromagnetic or solar energy is highly concentrated, each photovoltaic solar cell 508 will be subjected to intense heat and must be cooled effectively. The closed chamber 502 may contain at least one duct and a heat transfer media 510, which may be in liquid and/or vapor form. The closed chamber 502 may also contain a vapor phase volume 512. In operation, the liquid heat transfer media 510 absorbs heat from the backside of the one or more solar cells 508 thus heating the liquid and lowering its density. This causes the liquid to rise and set up convection currents as indicated by arrows 514. Heat is thus carried effectively to the large surface area inside of the fins 516 to be conducted convectively, as indicated by arrow 518, and thereby cooled by the fins 516. The fins 516 are cooled convectively by ambient air flow that carries away heat, as indicated by arrow 520.

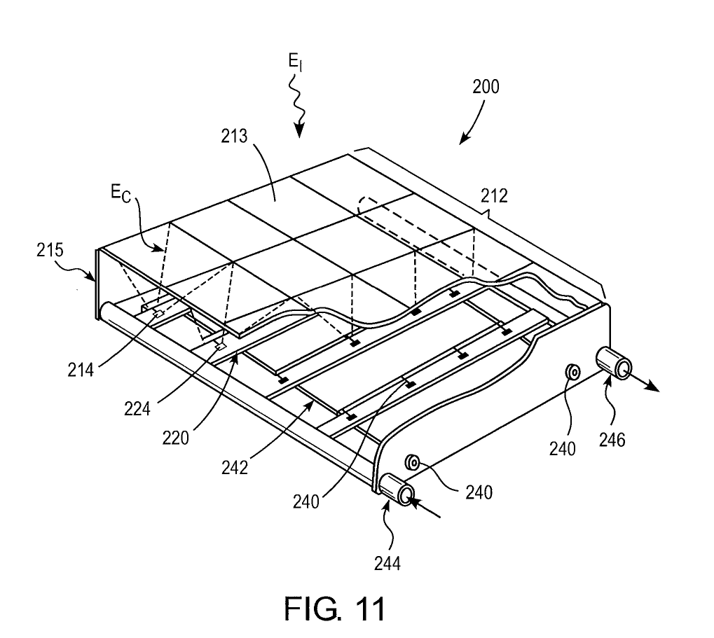

According to a further aspect of the present invention, an array can be formed, optionally from a plurality of the above described arrangements 100. One such array or module 200 formed according to the principles of the present invention is illustrated in FIG. 11. As illustrated therein, the array or module 200 comprises a concentrator 212 which receives incident electromagnetic energy E_{I}, and concentrates it (E_{C}). A single concentrator may be provided for the entire array or module 200. Optionally, a plurality of individual concentrators 213 can be associated with one another to form the overall concentrator 212. The concentrator 212 can have any of the features or characteristics of the concentrators 12, 112 described herein. The array 200 can be in the form of a one or two dimensional array. Thus, for example, the array 200 may be planar or curved in overall configuration.

A plurality of electromagnetic energy receiving devices 214 are provided to receive concentrated electromagnetic energy E_{C}. The electromagnetic energy receiving devices 214 can have any of the features or characteristics of the electromagnetic energy receiving devices 14, 114 described herein. The array or module 200 may comprise one or more electrical contacts 240 which commonly electrically connect all or some of the electromagnetic energy receiving devices 214. The contacts 240 may also be used to connect a plurality of modules 200 to one another. In addition, as described herein, the electromagnetic energy receiving devices 214 can be electrically connected with additional components, such as one or more printed circuit boards 242.

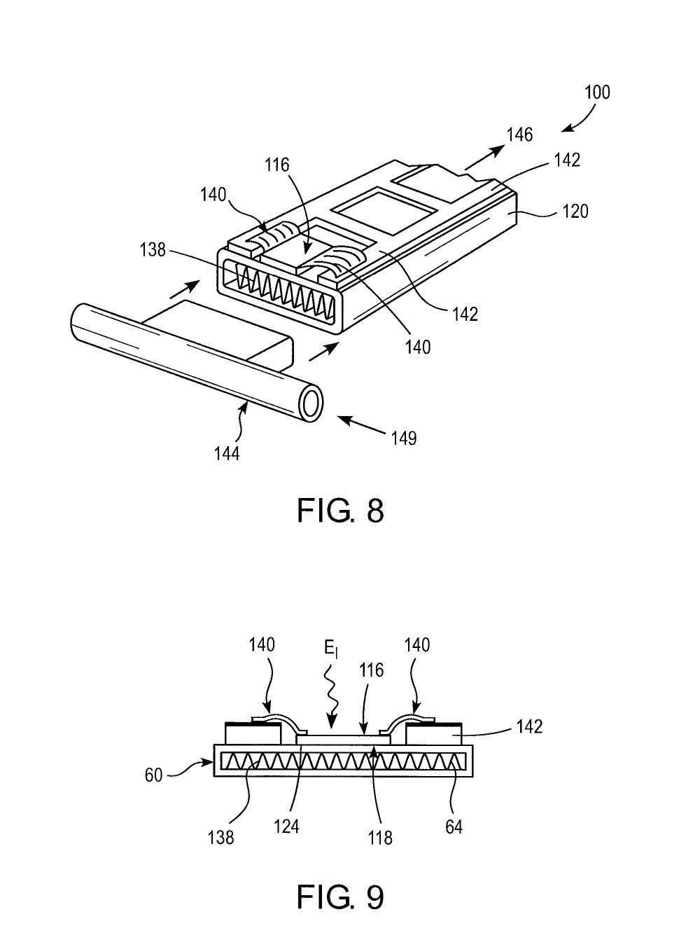

The plurality of electromagnetic energy receiving devices 214 are connected to one or more heat transport device 220. According to the illustrated embodiment, a single heat transport device 220 is associated with all of the electromagnetic energy receiving devices 214 of the array or module 200. However, it is contemplated that a different heat transport device can be associated with each individual electromagnetic energy receiving device to 214, or that a number of subgroups of electromagnetic energy receiving devices 214 each share a respective heat transport device. The at least one heat transport device to 220 can have any of the features or characteristics of the previously described heat transport devices 20, 120. Thus, as illustrated in FIG. 8, the device 220 can comprise a heat transfer media inlet 244 and outlet 246.

A thermal interface layer 224 is provided between a second surface of each electromagnetic energy receiving device 214, and a first surface of the at least one heat transport device to 220. The thermal interface layer 224 can have any of the features or characteristics of the previously described thermal interface layers 24, 124.

The array or module 200 may also be associated with a suitable tracking device, such as the tracking device 28 illustrated in FIGS. 2-3 and 4-5.

As illustrated in FIG. 11, the array or module 200 has a relatively low profile or form factor which lends itself to manufacture by automated mass production techniques thereby lowering the cost and improving the convenience associated with making such devices. By contrast, conventional solar or raise which possess high concentration capabilities are typically much larger and more complicated in their construction, thus requiring piecemeal manufacture and laborious assembly at the point of installation.

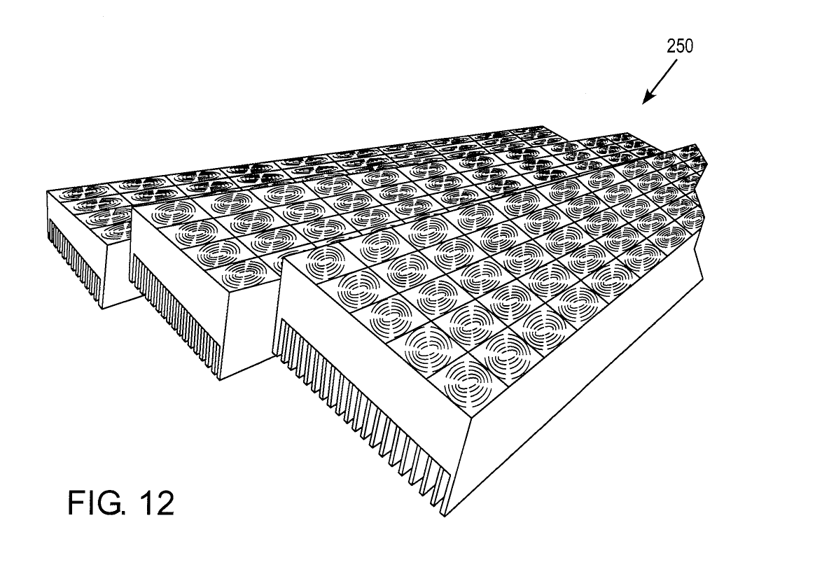

The array or module 200 may possess a modular construction. Each module would contain concentrator, electromagnetic energy receiving, heat transport and thermal interface components. Thus, by selecting the number of individual modules which can be connected together, one can easily select and change the overall size of the array or module 200. An array 250 formed from a plurality of modules is illustrated in FIG. 12. In addition, one can easily select and change the overall size of the tracking array (e.g., 400, FIGS. 4-5).

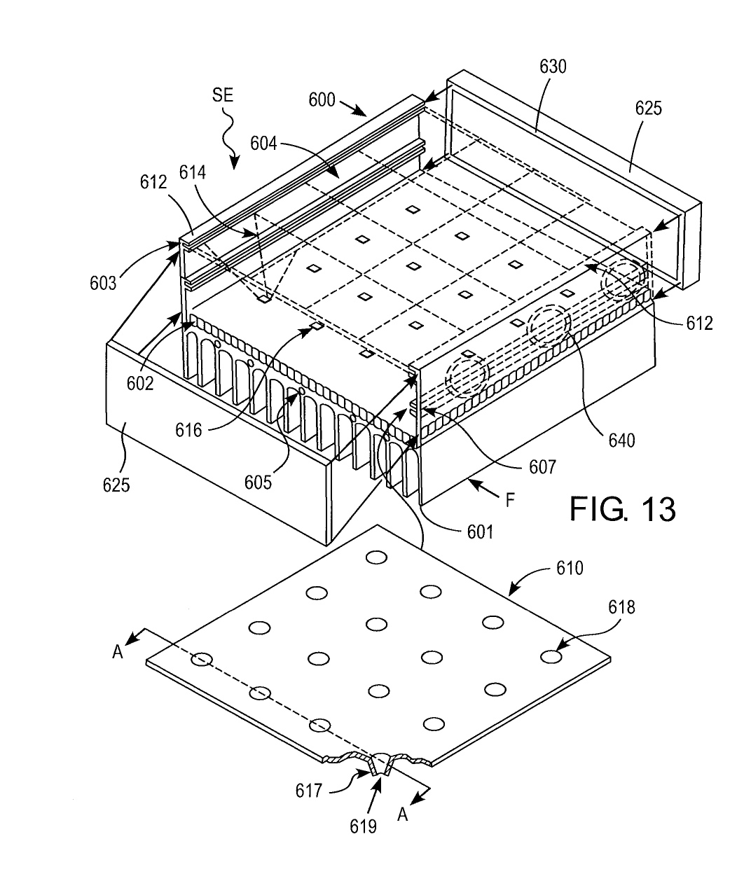

Arrangements 600, 600′ formed according to additional aspects of the present invention are illustrated in FIGS. 13-16. The arrangements 600, 600′ may optionally take to form of a compact high solar concentration photovoltaic system module. The arrangements 600, 600′ may comprise a heat transport device 601, 601′. According to the illustrated embodiment, the heat transport device 601, 601′ may comprise multi-fin heat sink. The heat transport device can be formed from any suitable material. According to one example, the heat transport device 601, 601′ is formed from a material having a high thermal conductivity, including any of the materials described herein associated with other heat transport device embodiments. As heat is received thereby, it may be spread and dissipated passively to the air by fins F underneath or carried away as usable heat by heat transfer media flow through channels 605 to connected piping (not shown).

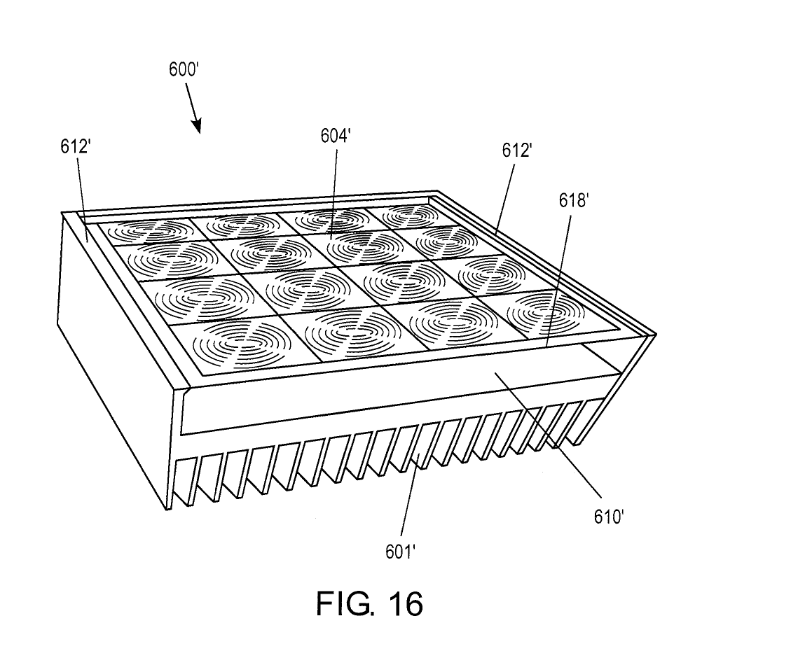

The arrangements 600, 600′ may additionally comprise at least one concentrator 604, 604′ for receiving incident electromagnetic energy S_{E}. According to the illustrative, non-limiting example, the concentrator 604, 604′ may comprise one or more of the optical elements previously described therein. For example, the concentrator may comprise a multiple-lens Fresnel lens array panel. This panel may optionally be mounted in grooves 603 of a frame or support 612, 612′. This panel may be in the form of a one or two dimensional array. Thus, for example, the panel may be in the form of a planar or curved array. The concentrator 604, 604′ is configured to concentrate and focus high-intensity electromagnetic or solar energy 614 of up to or greater than 1000× or less than 10,000× onto one or more electromagnetic receiving device(s) 616. The electromagnetic energy receiving device(s) may comprise one or more photovoltaic solar cell. The electromagnetic energy receiving devices of arrangement 600′ are present, but not visible in FIG. 16.

According to certain embodiments, the arrangements 600, 600′ or modules are designed, packaged and sealed for environmental protection while operating under extreme environmental conditions. The modules may be environmentally or hermetically sealed with a pressure balance to accommodate fluctuations and environment of conditions, such as temperature, pressure, moisture, etc. the overall design of the arrangements 600, 600′ may be designed for proper matching of the relative coefficients of thermal expansion between the components, parts and packaging materials which make up the arrangements or modules. As noted above, the concentrator 604, 604′, which may optionally be in the form of a panel, can be mounted in grooves 603 of a frame or support 612, 612′. According to certain embodiments, a seal is formed between the grooves 603 and those portions of the panel or concentrator 604, 604′ received therein. According to further embodiments, one or more sides of the module are sealed with cover plates 625 which can be secured in any suitable manner to the frame 612, 612′, such as by mechanical fasteners or adhesive. The cover plates 625 may optionally include a bead of elastomeric sealant or other gasket-like structure 630 to help improve the seal formed between the cover plates 625 and the frame 612, 612′. According to yet another optional embodiment, the arrangements 600, 600′ may optionally be provided with filters 640 that define a semi-permeable barrier between the outside environment and the interior portion of the module. The filters 640 served to provide an effective barrier to contamination, yet permit the external environmental pressure and pressure inside the module to equilibrate or fluctuate. According to one optional modification of this construction, the filters 640 may be replaced by substantially nonpermeable diaphragms which provide a barrier, yet also served to permit the pressures to equilibrate via flexure of the diaphragm inwardly are outwardly, as necessary.

To attain high-concentrations of solar energy requires accurate positioning of components to keep the solar rays focus on the solar-cells. To this end any suitable tracking system can be utilized in conjunction with the arrangements 600, 600′ including any of the tracking systems described herein. The arrangements 600, 600′ may additionally include one or more optical relocator 610, 610′ designed to re-direct possibly misaligned rays of energy onto a desired area of the one or more electromagnetic energy receiving device 616. It should be understood that any of the various embodiments described herein may optionally include a relocator device of the type described herein. In a more fundamental aspect, the relocator 610, 610′ comprises a member 617 constructed to re-direct incident electromagnetic energy S_{E} onto at least a portion of a first surface of an electromagnetic energy receiving device 616. The member 617 may comprise a first opening 618, 618′, a second opening 619, and converging side surfaces 620 extending between the first opening 618, 618′ and the second opening 619. Thus, the member 617 may be narrower at the bottom relative to the top. Here, the “top” is the side closest to incident electromagnetic energy. The first opening 618, 618′ may be formed such that the diameter thereof is larger than the beam width of concentrated energy transmitted from the at least one concentrator 604, 604′. The second opening 619 may be sized such that it is slightly larger than at least a portion of the first surface of the one or more electromagnetic energy receiving device 616. The converging side surfaces 620 may be provided with any suitable geometry or configuration. According to non-limiting examples, the converging side surfaces 620 can be multifaceted, cup-shaped, frustoconical, or in the form of a regular or irregular polygonal frustum. The slope of the side surfaces 620 may all be the same, or may differ relative to each other. The slope of one or more side surfaces 620 may be constant or variable. According to further non-limiting examples, one or more of the side surfaces 620 may take the form of a curved shape, an irregular polygon, a triangle, a rectangle, a square, a trapezoid or other polygon. The converging side surfaces 620 may optionally be polished, anodized, or otherwise coated or treated so as to enhance the degree of optical reflection. According to an alternative embodiment, an optical material 623 having an index of refraction greater than air may be provided in the member 617 between the first and second openings 618, 618′, 619 which has the effect of additionally concentrating the incident electromagnetic energy. The optical material may comprise one or more of: plastic, acrylic material, quartz, glass, metal, semiconductor material, films and fluid-filled structures. According to yet another optional embodiment, at least a portion of the side surfaces 620 may be formed from or coated with a photovoltaic material 651, and electrically connected to the output of the arrangement 600, 600′ or device.

References made herein to photovoltaic material are intended to encompass any material for conversion of energy incident therein to electricity that can be applied as a coating. Illustrative, non-limiting examples include: cadmium telluridium, copper indium gallium diselenide, amorphous silicon, dye sensitized nano-sized titanium dioxide particles, and (poly(N-vinylcarbazole) PVK nano-composites.

According to an additional embodiment, the relocator comprises a plate 610, 610′ having a plurality of members 617 formed therein. The relocator plate 610, 610′ may be mounted within slots 607 of a frame or support 612, 612′. The relocator plate 610, 610′ can be formed by any suitable technique, such as by punching, molding or stamping. The relocator plate 610, 610′ can be formed from any suitable material such as a metal like an aluminum or aluminum alloy. Optionally, the plate may be coated with a material to enhance its reflective or optical properties, such as a metal oxide coating. Thus, the relocator plate 610, 610′ is capable of final solar concentration and/or image re-location. A misaligned energy beam enters first opening 618, is reflection down off the converging sides 620 of the member 617, and exits the second opening 619 where it is thereby re-directed to the desired location on an electromagnetic energy receiving device 616.

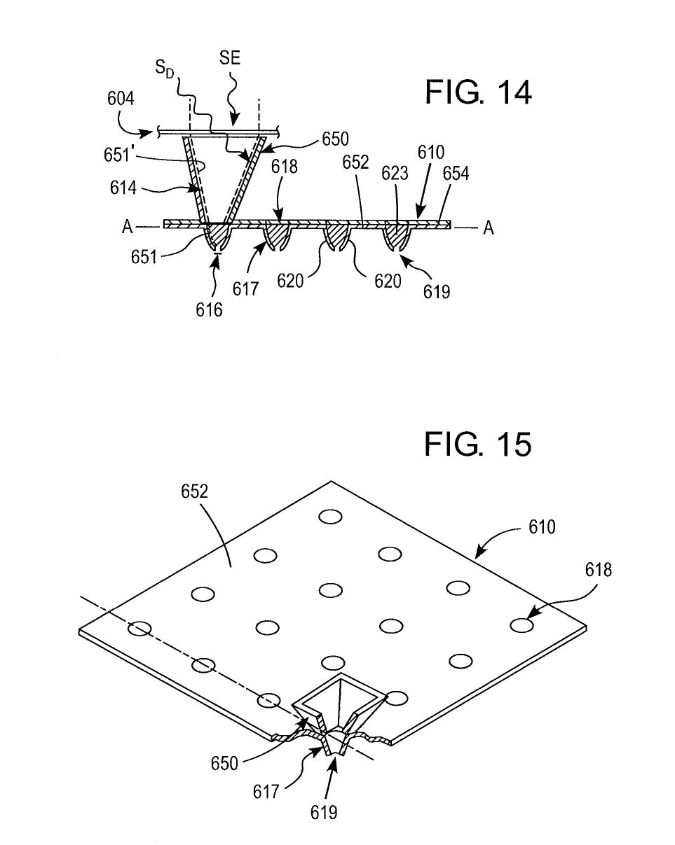

FIGS. 14 and 15 illustrate one optional modification of the relocator plate 610, 610′. As illustrated therein, an extension 650 may be provided on the top surface of the relocator plate 610, 610′ that extends all the way up to the primary optics or concentrator 604, 604′. According to this embodiment, essentially all of the concentrated light 614, and any diffuse or non-direct beam light SD will be collected within the extension 650 and guided to the one or more electromagnetic energy receiving device 616 in the manner described a above. The interior of the extension 650 may be provided with a surface finish, coating, or with an insert of optical material, consistent with the features of the other collector embodiments described herein. The interior of the extension may also optionally be at least partially formed from or coated with a photovoltaic material 651′.

As a more general principle, any surface of any of the various components of the arrangements described in the present disclosure that is exposed directly or indirectly to solar or electromagnetic energy can be coated with a suitable photovoltaic material. Thus, the energy to electricity conversion for the arrangement is maximized. By way of example, the top surface 652 of a relocator plate (e.g., 610, 610′) can be provided with a coating 654 of any suitable photovoltaic material, such as those photovoltaic materials described above.

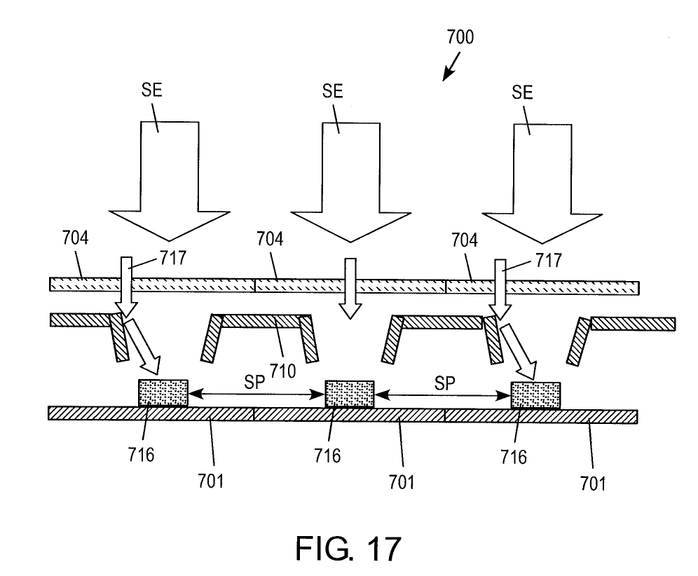

Additional advantageous aspects of the present invention can be gleaned by reference to the illustrative arrangement 700 depicted in FIG. 17. It should be understood that the principles associated with the following discussion of the arrangement 700 depicted in FIG. 17 is equally applicable to any or all of the previously described embodiments herein. By the same token, the various features, constructions and advantages of any of the previously described embodiments can also be incorporated or added to the arrangement 700. The arrangement 700 may optionally be in the form of an array. The array can comprise a one or two dimensional array. Therefore, the array can be, for example, either planar and/or curved. Incident electromagnetic energy or sunlight SE passes through at least a first concentrator element 704, and then through an optional relocator element or plate 710 optionally having a construction as described herein in connection with previously described embodiments. Thus, any misaligned energy 717 is refocused and redirected onto at least a portion of a surface of an electromagnetic energy receiving device 716. The electromagnetic energy receiving device 716 can have any of the previously described constructions. In particular, the energy receiving device 716 has a relatively small footprint or surface area. According to nonlimiting examples, the electromagnetic energy receiving device can have a footprint which is on the order of 10 square mm to 1 square cm. The at least one electromagnetic energy receiving device 716 is mounted to at least one heat transport device 701. The heat transport device 701 can have any of the previously described constructions. According to the illustrative arrangement 700, the surface area of the concentrator element 704 and the surface area of the heat transport device 701 can be approximately the same. The at least one electromagnetic energy receiving device 716 may be roughly centrally located on the heat transport device 701. By this arrangement, which utilizes the beneficial concentration and heat transport features of the present invention, in combination with the relatively small electromagnetic energy receiving device 716, which may comprise a photovoltaic solar cell, provides the additional advantage of a large spacing SP between electromagnetic energy receiving devices 716. This spacing SP further facilitates the efficient cooling of the arrangement 700, thereby providing the ability to operate under conditions of high solar concentration, and with optimal conversion of electromagnetic energy to other force of energy, such as the photovoltaic conversion of sunlight to electricity.

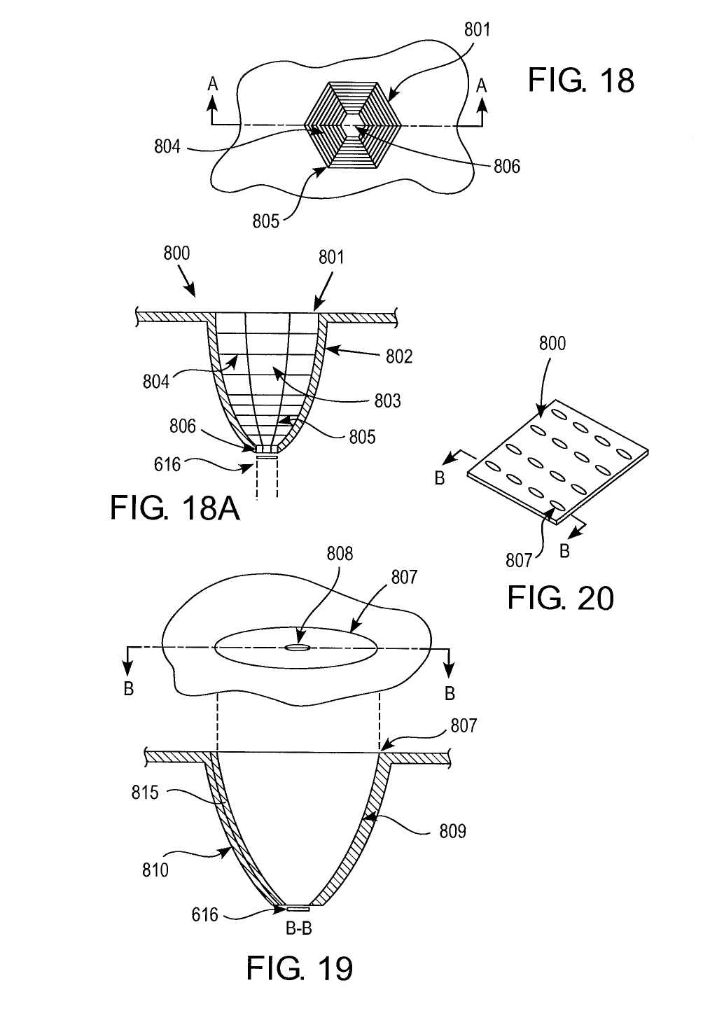

FIGS. 18-20 depict additional illustrative embodiments of the optical relocator. As illustrated therein, The optical relocator 800 may include at least one member generally shaped like a cup with side walls 802 in the form of numerous polygon-shaped surfaces 803. The top and bottom sides 801 and 804 of the polygons are parallel to each other where as the vertical sides 805 of the polygons are not parallel, but instead converge in the top to bottom direction. The parallelism of the top and bottom sides 801 and 804 and the convergent shapes of the vertical sides 805 of the trapezoids create a progressively decreasing circumference in the rings, with the circumference decreasing from the top to bottom direction. This shape enables collection of misaligned light falling into it through multiple internal reflections and ensures that such misaligned light falls on the electromagnetic energy receiving device 616 through a bottom opening 806. FIG. 18 is a top view showing the polygon shape with decreasing circumference from top to bottom. Although FIG. 18 depicts a hexagonal shape, the invention is not so limited, and any suitable polygon, round, oval, etc. shape is contemplated. The polygons could be shaped to create an elongated version of the shapes shown in the illustrated embodiments in which one or more of the sides of the polygon are much longer than the other, thereby defining a shape that looks generally like an elongated though. FIGS. 18-19 also show a top rim or opening 807, inner surface 809, outer surface 810, and bottom opening 806.

The area between the inner surface 809 and the outer surface 810 could contain or be formed from an optically transparent or opaque material. When the area is made up of opaque material, the inner surface is made of reflective surface accomplished with or without reflective coating, sputtering, etching, polishing or surface treatment. When the area between the inner surface 809 and outer surface 810 contains or is made from a transparent material, the transparent material could be doped to create graded refractive index so that the light falling on the inner surface is reflected back through total internal reflection. The light that falls on any part of the surface 809 is guided to the bottom opening 806 through total internal reflection to the electromagnetic energy receiving device 616. The inside surface 809 may also be at least partially made of, or coated with a photovoltaic material, so that any misaligned light could be converted to electricity.

FIG. 20 shows an optical relocator 800 in the form of a plate having an array of members. The array could range from 2×1 linear arrays to linear array of 10,000×1 or two dimensional arrays ranging from 2×2 to 10,000×10,000 in a single structure. Many such linear arrays or two dimensional arrays could be assembled to construct very large linear or two dimensional arrays covering many acres. The sides of the polygons described herein could range from 1 nm to 100 meters.

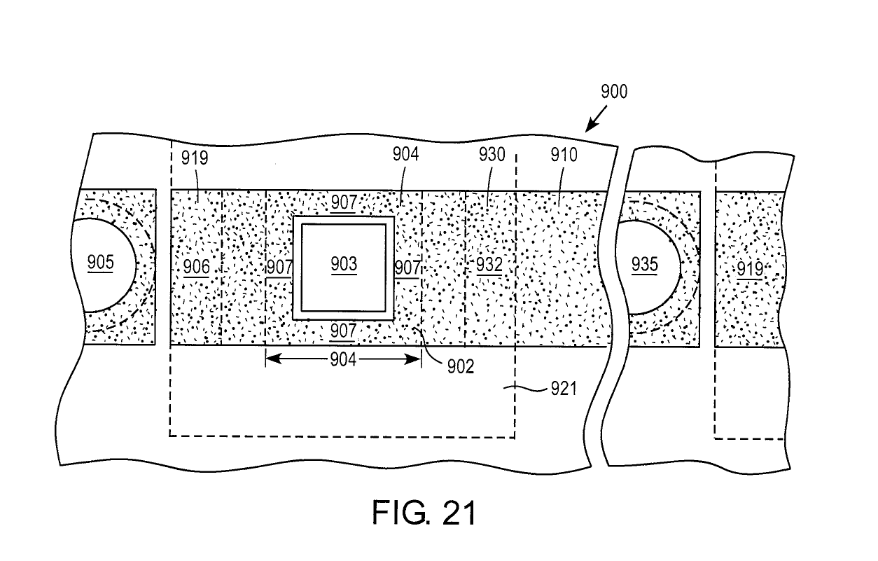

FIGS. 21-26 show optional mounting and electrical connection arrangements for an electromagnetic energy receiving device, such as a solar cell, on a flexible circuit or PC Board 900. The arrangement can be generally characterized by the positioning of the solar cell with respect to the incident light after one or multiple stages of light energy concentration and light collection, and also by mounting of the solar cell for efficient heat transfer to a cooling structure. Any dimensions mentioned in association with FIGS. 21-26 are for illustrative purposes, whereas the dimensions can vary widely depending on actual implementation.

As shown in FIG. 21, the solar cell 903 with electrical contact surfaces 904 is mounted at contact area 907 of the electrical circuit trace 910 of the flexible circuit or PC Board 900. The electrical circuit contact surfaces 904, 919 and 930 are electrically conductive, non-oxidizing sliding surfaces designed to allow for material thermal expansion mismatching. The contact material can comprise any suitable material like gold, or even a designer composite material of the type described in copending provisional and non-provisional U.S. patent application Nos. 61/071,412 and ______ entitled “Composite Material Compositions, Arrangements and Methods Having Enhanced Thermal Conductivity Behavior.” The contact is plated on the copper trace 910 at trace surfaces 906 and 907 of the flexible circuit or PC Board 900. Other high conductivity materials could be used in instances in the present invention where copper or gold or other high conductivity metals and alloys are specifically identified, suitable substitutes include the above-mentioned designer composite material described in the above-mentioned U.S. patent applications.

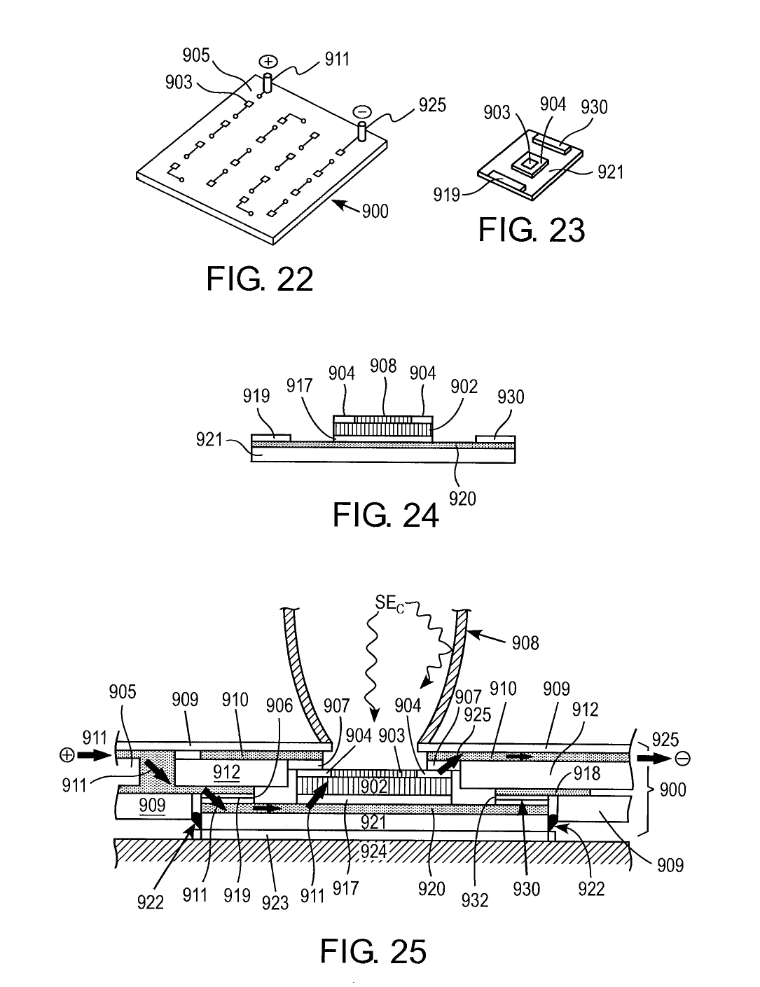

FIGS. 21-22 also illustrate a copper plated through-hole 905 for connecting the solar cell to, for example, protection diodes and the like mounted on a PCB surface. The plated-through-hole also allows for serial electrical connectivity of the solar cells 903 as illustrated in FIG. 22. The PCB copper trace 906 is also shown. The total area of the solar cell package is represented by 904 where are the active area of the solar cell is represented by 903. The total area of the solar cell package 904 can be, for example, on the order of 10 nm²-10 cm². The total active area of the solar cell 903 can be, for example, on the order of 1 nm²-9 cm².

FIGS. 23-24 also show an aluminum nitride substrate 921 on which the solar cell package can be mounted. Referring to FIG. 24, 902 is the solar cell semiconductor substrate of which the electrical contact area 904 is plated gold. The semiconductor substrate 902 is soldered to the electrically conductive circuit layer 920 of electrical insulator, high-thermally conductive aluminum nitride substrate 921. The electric circuit contacts 919 and 930 are plated on the electrically conductive surface 920, and mates when assembled, with surfaces 906 and 932. The assembly is mounted in the PCB 900 as depicted in FIG. 25.

FIG. 25 depicts the details of a construction and assembly including an optical relocator 908, which not only allows concentrated/collected light to directly fall on the active area of the solar cell 903, but also collects misaligned light and directs it onto the solar cell 903 as well. The solar cell 903 is mounted not only to the flexible circuit or PC board 900, but is also mounted and connected to the heat sink or heat transport device 924 through a high thermal conductivity thermal interface material 923. The construction of the optical relocator 908 with its lower opening interface ensures that misaligned light does not fall on the flexible circuit or board 900, but instead falls only on the active area of the solar cell 903.

According to the illustrated embodiment, the multiple layer flexible circuit or board 900 is made of insulation 909, 912, and copper plated surfaces 910, 918, anode 911 and cathode 925. Referring to FIG. 25, the electrical circuit path follows the arrows in FIG. 25 from the anode lead 911 to the gold contacts 906, 932 and contact 919 on through the electrical conductor 920 to and up through the solder layer 917 through the solar cell substrate 902 and on to the active electromagnetic energy receiving device 903, then exiting through gold contact 904 in contact with gold plated area 907. The electrical circuit continues through conductor 910 to the cathode 925 where the circuit continues on to the next plated-through-hole anode 935.

As noted previously, the thermal interface material 923 can made of a high thermal conductivity composite with eccentric thermal conductivity of lateral thermal conductivity in the X and Y direction much higher than in the vertical Z direction, thus very efficiently spreading the heat to a large surface of 924 is achieved.

FIG. 25 also shows a silicone elastomer or any other elastomeric material 922 holding the aluminum nitride substrate to the flexible circuit or board. The elastomer 922 accommodates for any potential differential coefficient of thermal expansion. The design of the assembly accounts for and ensures the required design and manufacturing requirements for CTE matching of the different interfacing materials in the construction of the assembly and elastomers like 922 to accommodate for any potential mismatches resulting in dislocations and disconnections. The design, construction, assembly and manufacturing of the subsystem shown in FIGS. 21-25 ensures maximum light energy collection, efficient conversion of the light energy to electricity, efficient heat spreading, heat transfer and cooling of the solar cell, while the mechanical, electrical and structural integrity of the complete assembly is maintained to accommodate for severe environmental conditions. The design of the assemblies shown in FIGS. 21-25, as well as the rest of the description along with respective figures in this disclosure is especially focused design for manufacturing (DFM), design for test (DFT) and design for calibration (DFC) so that the complete assembly could be manufactured with existing pick place assembly lines of most of the contract manufacturing infrastructure in the industry.

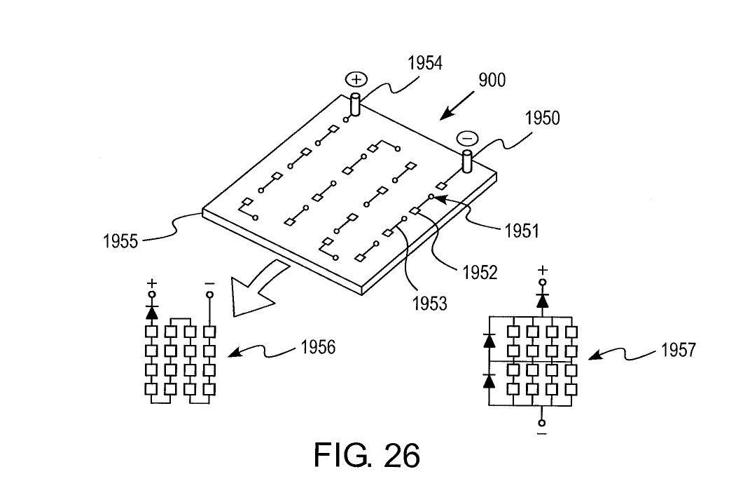

An additional optional embodiment formed according to the principles of the present invention is illustrated in FIG. 26. The arrangement of FIG. 26 illustrates embodiments of how each solar cell assembly can be arranged in a fully populated PCB 900. According to the illustrated embodiment, solar cells 1952 are mounted on a flexible circuit or a standard type PC board 1955 as shown in FIG. 26. The cells 1952 are connected by a lead 1953 on the flexible circuit or board 1955 to the through-hole contact 1951, to the protection diodes, blocking diodes, or bypass diodes, as shown in series 1956 or parallel 1957 to obtain different voltage and current combinations. The series 1956 and parallel 1957 arrangements are only examples. With a solar cell array configuration, linear and two dimensional arrays of any size of solar cells and the total number of solar cells in a row, and the complete overall array configuration dictate the diode selection. The layout shown on the board or flexible circuit 1955 in FIG. 26 can have a series connection 1956 with 48 V across the electrode leads 1950 and 1954 only as an example. Other voltage and current combinations result based on the size of the solar cell, efficiency of the solar cell, total number of solar cells on the assembly, total light energy incident on the solar cells and whether it is a series or parallel connection, among other possible factors. In the examples shown in 1956 for series connection the peak output is 48 volts at 0.5 amps current to produce 24 watts of power output and in 1057 for parallel connection the peak output is 24 Volts at 2 amps current to produce 24 watts of power output.

In order to further elucidate the benefits and advantages of the present invention, reference will now be made to the following illustrative, non-limiting examples.

### Examples

Heat greater than 100 W/cm² occurs at concentrations of approximately 1,000 suns or more. It should be noted that electronic devices melt in seconds without proper cooling at this level of heat density.

It has been difficult to concentrate more than 600 suns on a solar cell of 1 cm² in size, mainly because the heat density produced melts the solar cell, if efficient heat transfer techniques are not used.

A solar-cell testing apparatus, associated with sidereal solar tracking apparatus using a modified equatorial telescope mount was retrofitted with the following capabilities: The degree of solar irradiance was controlled with a series of masks having different aperture sizes, thereby allowing concentrations from 1-Sun to 1688-Suns to be produced. Solar energy was focused to an area of 1 cm²; the cell surface temperature was measured with a non-contact IR sensor; emf and ampere values of a single 1 cm² solar cell at various X-suns was measured; and heat flux at various X-suns was also measured for system calibration.

A conventional solar cell was combined with a cooling arrangement formed according to the present invention. A conventional 1 square cm solar cell (commercially available from Spectrolabs Inc.) was utilized. One such solar cell was stripped of its packaging and attached to a thermal transport block formed of a copper alloy via a thin layer of thermal interface material formed from a silver alloy material. For comparison, another arrangement like the one described above was prepared, except the packaging of the solar cell was left intact. For purposes of comparison, a conventional solar cell assembly without the cooling arrangement of the present invention was utilized. These arrangements we evaluated at various X-suns using the above-described experimental set-up. The results of this comparison is summarized in the following Table I.

Table I

TABLE I

| SOLAR CELL THERMAL TEST | | | | | |
|---|---|---|---|---|---|
| 1 × 1 cm Bare Cell w/Interconnects | | | | | |
| Elec. Bin: 3 (6.490A-6.684A) | | | PRE-MOUNTED SOLAR CELL THERMAL TEST | | |
| (Cell Thermal Test Run URL-AA-4) | | | 1 × 1 cm Type A w/Blocking Diode | | |
| Solar | Invention | Conventional | (Cell Thermal Test Run URL AA-3) | | |
| Irradiance | Cell | cell Data | Solar | Cell Surface Temperature | |
| Conc. | Surface | (interpolated) | Irradiance | Invention | Conventional cell |
| Factor | Temp | Temp | Conc. Factor | Data | (interpolated) |
| (X Suns) | (deg C.) | (deg C.) | (X Suns) | (deg C.) | (deg C.) |
| 1 | 13 | | 1 | 14 | |
| 9 | 13 | 30 | 9 | 15 | 30 |
| 25 | 14 | 35 | 25 | 16 | 35 |
| 81 | 16 | 40 | 81 | 19 | 40 |
| 169 | 18 | 45 | 169 | 22 | 45 |
| 289 | 21 | 60 | 289 | 27 | 60 |
| 441 | 23 | 70 | 441 | 37 | 70 |
| 625 | 28 | 83 | 625 | 38 | 83 |
| 841 | 32 | 95 | 841 | 47 | 95 |
| 1089 | 36 | 105 | 1089 | 53 | 105 |
| | | | 1688 | 63 | N/A |

As evident from the above, significant gains in cooling and heat transport efficiency is obtained, relative to the conventional arrangement, by the present invention.

All numbers expressing quantities of ingredients, constituents, reaction conditions, and so forth used in the specification are to be understood as being modified in all instances by the term “about.” Notwithstanding that the numerical ranges and parameters set forth, the broad scope of the subject matter presented herein are approximations, the numerical values set forth are indicated as precisely as possible. Any numerical value, however, may inherently contain certain errors resulting, for example, from their respective measurement techniques, as evidenced by standard deviations associated therewith.

Although the present invention has been described in connection with preferred embodiments thereof, it will be appreciated by those skilled in the art that additions, deletions, modifications, and substitutions not specifically described may be made without departing from the spirit and scope of the invention. Terminology used herein should not be construed in accordance with 35 U.S.C. §112, ¶6 unless the term “means” is expressly used in association therewith.

We claim:

1. An arrangement comprising:
a concentrator constructed and arranged to receive incident electromagnetic energy and to concentrate the incident electromagnetic energy to a greater intensity level;
an electromagnetic energy receiving device comprising a first surface constructed and arranged to receive the concentrated electromagnetic energy, and a second surface opposite the first surface;
at least one optical relocator constructed and arranged to re-direct concentrated electromagnetic energy onto at least a portion of the first surface;
a heat transport device comprising at least one duct and a first surface; and
a thermal interface layer physically connected to at least a portion of the second surface of the electromagnetic energy receiving device and the first surface of the heat transport device, the thermal interface material being thermally conductive, electrically conductive, or both.

2. The arrangement of claim 1, wherein the concentrator comprises a lens.

3. The arrangement of claim 1, wherein the concentrator comprises a Fresnel lens, and the lens is constructed from an optical material.

4. The arrangement of claim 1, wherein the concentrator comprises a one or two dimensional array of lenses.

5. The arrangement of claim 1, wherein the concentrator is constructed to magnifying the intensity of the sun by at least 10 times

6. The arrangement of claim 1, wherein the concentrator is constructed to magnifying the intensity of the sun by at least 1,000 times.

7. The arrangement of claim 6, wherein the concentrator is constructed to magnifying the intensity of the sun by at least 1,688 times.

8. The arrangement of claim 7, wherein the concentrator is constructed to magnifying the intensity of the sun by at least 2,000 times.

9. The arrangement of claim 8, wherein the concentrator is constructed to magnifying the intensity of the sun by at least 10,000 times.

10. The arrangement of claim 1, wherein the electromagnetic receiving device comprises at least one photovoltaic solar cell, the photovoltaic solar cell having a first surface defining an active area of 1 nm²-1,000 mm².

11. The arrangement of claim 10, wherein the first surface of the solar cell has dimensions of about 1 square cm.

12. The arrangement of claim 10, wherein the first surface of the solar cell has dimensions of about 1 square mm.

13. The arrangement of claim 10, wherein the first surface of the solar cell has dimensions of about 4 square mm.

14. The arrangement of claim 10, wherein the solar cell does not include electronic packaging materials.

15. The arrangement of claim 1, wherein the electromagnetic receiving device comprises at least one thermal receptor.

16. The arrangement of claim 1, wherein the heat transport device is formed, at least in part, by at least one of: aluminum, aluminum alloy, copper and a copper alloy.

17. The arrangement of claim 1, further comprising a heat transfer media at least partially within the at least one duct of the heat transfer device.

18. The arrangement of claim 17, wherein the heat transfer media comprises one or more of: water, an organic liquid, an inorganic liquid, a biological liquid, steam, oil, and solid particles.

19. The arrangement of claim 17, wherein the heat transfer media comprises a dispersion or an emulsion.

20. The arrangement of claim 17, wherein the heat transfer media comprises organic liquid.

21. The arrangement of claim 1, wherein the thermal interface layer is composed, at least in part, from one or more of: a multiphase material, a silver alloy, a liquid metal, a liquid metal alloy, a tin-indium alloy, a tin-bismuth alloy, and a lead-free solder.

22. The arrangement of claim 1, wherein the thermal interface layer has a composition comprising: thermal grease, solder, polymer, inorganic material, liquid metal, liquid metal alloy, various sizes of structures in micro, nano or other dimensions including tetrapods and millipods, films of a variety of thicknesses, being at least thermally conductive to ensure efficient heat transport path, which also may include electrical conductivity provided through the same or an alternate path or portion of the path as the thermal transport path.

23. The arrangement of claim 1, wherein the thermal interface layer forms at least part of an electrode.

24. The arrangement of claim 1, wherein the heat transport device comprises at least one inlet and at least one outlet.

25. The arrangement of claim 1, wherein the at least one heat transport device is in direct contact with the entire second surface of the electromagnetic energy receiving device via the thermal interface layer.

26. The arrangement of claim 1, further comprising a tracking device for tracking the position of a source of electromagnetic energy.

27. The arrangement of claim 26, wherein the tracking device moves along at least 2 axes to track the location of the source of electromagnetic energy.

28. The arrangement of claim 26, wherein the tracking device moves along at least 3 axes to track the location of the source of electromagnetic energy.

29. The arrangement of claim 1, wherein the heat transfer device comprises a closed chamber.

30. The arrangement of claim 1, wherein the at least one optical relocator is formed, at least in part, from an opaque material.

31. The arrangement of claim 1, wherein the optical relocator is formed, at least in part, from a transparent material.

32. The arrangement of claim 31, wherein the transparent material comprises a graded refractive index.

33. An arrangement comprising:
a photovoltaic solar cell comprising a first surface for receiving concentrated solar energy incident thereon, and a second opposing surface;
a heat transport device comprising at least one duct and a first surface; and
a thermal interface layer physically connected to the second surface of the solar cell and the first surface of the heat transport device, the thermal interface layer being both electrically and/or thermally conductive;
wherein the arrangement converts the concentrated solar energy to at least 37 Watts of DC electricity/cm² of photovoltaic cell area.

34. The arrangement of claim 33, wherein the incident solar energy is concentrated to at least about 1,688 suns.

35. The arrangement of claim 33, further comprising a concentrator constructed and arranged to receive solar energy, to concentrate the solar energy, and to direct the concentrated solar energy onto the first surface of the solar cell.

36. The arrangement of claim 33, wherein the concentrator comprises a Fresnel lens.

37. The arrangement of claim 33, wherein the Fresnel lens is constructed from an acrylic.

38. The arrangement of claim 33, wherein the electromagnetic receiving device comprises at least one photovoltaic solar cell, the photovoltaic solar cell having a first surface defining an active area of 1 nm²-1,000 mm².

39. The arrangement of claim 33, wherein the first surface of the solar cell has dimensions of 1 square cm.

40. The arrangement of claim 33, wherein the first surface of the solar cell has dimensions of about 1 square mm.

41. The arrangement of claim 33, wherein the first surface of the solar cell has dimensions of about 4 square mm.

42. The arrangement of claim 33, wherein the solar cell does not include electronic packaging materials.

43. The arrangement of claim 33, wherein the heat transport device is formed, at least in part, by a copper alloy.

44. The arrangement of claim 33, further comprising a heat transfer media at least partially within the at least one duct of the heat transfer device.

45. The arrangement of claim 43, wherein the heat transfer media comprises water.

46. The arrangement of claim 33, wherein the thermal interface layer is composed, at least in part, from a silver alloy.

47. The arrangement of claim 33, wherein the thermal interface layer has a composition comprising: thermal grease, solder, polymer, various sizes of structures in micro, nano or other dimensions, films of a variety of thicknesses, being at least thermally conductive to ensure efficient heat transport path, which also may include electrical conductivity provided through the same or an alternate path or portion of the path as the thermal transport path.

48. The arrangement of claim 33, wherein the thermal interface layer forms at least part of an electrode.

49. The arrangement of claim 33, wherein the heat transport device comprises at least one inlet and at least one outlet.

50. The arrangement of claim 33, wherein the at least one heat transport device is in direct contact with the entire second surface via the thermal interface layer.

51. An array comprising:
at least one concentrator, the at least one concentrator constructed and arranged to receive incident electromagnetic energy and to concentrate the incident electromagnetic energy to a greater intensity level;
a plurality of electromagnetic energy receiving devices, each device comprising a first surface constructed and arranged to receive concentrated electromagnetic energy, and a second surface opposite the first surface;
at least one optical relocator constructed and arranged to re-direct concentrated electromagnetic energy onto at least a portion of the first surface;
at least one heat transport device comprising a first surface; and
a thermal interface layer physically connected to at least a portion of the second surface of the electromagnetic energy receiving device and the first surface of the heat transport device, the thermal interface material being thermally conductive, electrically conductive, or both.

52. The array of claim 51, wherein the at least one heat transport device comprises at least one duct.

53. The array of claim 51, wherein the electromagnetic energy is concentrated by at least 1,000 times.

54. The array of claim 51, wherein the electromagnetic energy is concentrated by at least 1,600 times.

55. The array of claim 51, wherein the electromagnetic energy is concentrated by at least 2,000 times.

56. An arrangement comprising:
at least one concentrator constructed and arranged to receive incident electromagnetic energy and to concentrate the incident electromagnetic energy to a greater intensity level;
at least one electromagnetic energy receiving device comprising a first surface constructed and arranged to receive the concentrated electromagnetic energy;
a heat transport device in thermal communication with the at least one electromagnetic energy receiving device; and
at least one optical relocator constructed and arranged to re-direct concentrated electromagnetic energy onto at least a portion of the first surface.

57. The arrangement of claim 56, wherein the optical relocator comprises a member having a first opening, a second opening and side surfaces connecting the first and second opening, the side surfaces converging toward the second opening.

58. The arrangement of claim 56, wherein one or more of the side surfaces comprise a cup-shape, frustoconical shape, a regular or irregular polygonal frustum, a constant slope, or a variable slope.

59. The arrangement of claim 57, wherein at least a portion of the side surfaces are polished, anodized, or coated in a manner so as to improve the reflective properties thereof.

60. The arrangement of claim 56, wherein an optical material is contained between the first and second openings, the optical material providing further concentration of the incident electromagnetic energy.

61. The arrangement of claim 56, wherein the member comprises a relocator extension extending from the first opening to the at least one concentrator.

62. The arrangement of claim 61, wherein the relocator extension has an inner surface comprising a photovoltaic material.

63. The arrangement of claim 56, wherein the optical relocator comprises a plate having a plurality of depressions formed therein, wherein each depression comprises a first opening, a second opening and side surfaces connecting the first and second opening, the side surfaces converging toward the second opening.

64. The arrangement of claim 63, comprising a plurality of electromagnetic energy receiving devices, each electromagnetic energy receiving device comprising a first surface constructed and arranged to receive re-directed electromagnetic energy from a respective second opening of a respective depression.

65. The arrangement of claim 56, wherein a least one concentrator has a first surface area, and the at least one heat transport device has a second surface area, the first surface area being approximately equal to the second surface area, and wherein the at least one electromagnetic energy receiving device is approximately centrally located on the at least one heat transport device.

66. The arrangement claim 65, wherein the at least one electromagnetic energy receiving device has an area no greater than approximately 1 mm×1 mm.

67. An environmentally sealed module comprising the arrangement of claim 56.

68. The module of claim 67 comprising at least one filter or membrane providing at least a semi-permeable barrier between the environment and the interior of the module.

69. An arrangement comprising:
a circuit board comprising an upper electrically insulating layer having an opening disposed therein;
an electromagnetic energy receiving device comprising a first surface having an active area and a second opposing surface, the active area in communication with the opening in the insulating layer; and
a relocator comprising a member, the member comprising a first opening, a second opening, and converging side surfaces connecting the first and second openings, the side surface converging toward the second opening, the second opening disposed for direct communication with the opening in the insulating layer;
wherein electromagnetic energy incident upon the relocator is directed onto the active area of the electromagnetic energy receiving device.

70. The arrangement of claim 69, wherein the electromagnetic energy receiving device comprises a photovoltaic solar cell.

71. The arrangement of claim 69, wherein the electromagnetic energy receiving device is connected to the circuit board by one or more layers of electrically conductive material.

72. The arrangement of claim 71, further comprising a heat transport device, and thermal interface layer, the thermal interface layer being electrically conductive, thermally conductive, or both; wherein the circuit board and the electromagnetic energy receiving device is connected to the heat transport device via the thermal interface layer.

73. An arrangement comprising:
a circuit board; and
an array of solar cells disposed on the circuit board;
wherein the solar cells of the array are electrically connected to at least one of the protection diodes, blocking diodes, or bypass diodes, in either a series or parallel relationship so as to provide a desired voltage and current combination.

74. An arrangement comprising:
a circuit board comprising an upper electrically insulating layer having an opening disposed therein;
an electromagnetic energy receiving device comprising a first surface having an active area and a second opposing surface, the active area in communication with the opening;
an electrical contact area in electrical communication with the active area;
an optical relocator comprising a member, the member comprising a first opening, a second opening, and converging side surfaces connecting the first and second openings, the side surfaces converging toward the second opening,
and the second opening disposed for direct communication with the opening in the upper insulating layer;
wherein electromagnetic energy incident upon the relocator is directed onto the active area of the electromagnetic energy receiving device.

75. The arrangement of claim 74, wherein the electrical contact area comprises gold.

76. The arrangement of claim 74, wherein the electrical contact area is disposed for sliding electrical contact with the circuit board.

77. The arrangement of claim 74, wherein the electrical contact area surrounds the active area.

78. The arrangement of claim 74, further comprising:
an electromagnetic energy receiving device substrate;
wherein the electrical contact area is plated on the substrate.

79. The arrangement of claim 78, further comprising an electrically conductive circuit layer, and wherein the substrate is electrically and physically connected to the electrically conductive circuit layer.

80. The arrangement of claim 79, further comprising a thermally conductive electrical insulator layer, wherein the electrically conductive circuit is disposed on the electrical insulator layer.

81. The arrangement of claim 80, wherein the electrical insulator layer comprises aluminum nitride.

82. The arrangement of claim 80, further comprising a plurality of electrical contacts disposed on the electrically conductive circuit layer.

83. The arrangement of claim 82, further comprising at least one cathode and at least one anode.

84. The arrangement of claim 83, further comprising an elastomer material disposed between the electrical insulator layer and the circuit board.

85. The arrangement of claim 74, further comprising a heat transport device, and a thermal interface layer, the thermal interface layer being electrically conductive, thermally conductive, or both.

86. The arrangement of claim 85, further comprising a thermally conductive electrical insulator layer, and the thermal interface layer disposed between the heat transport device and the electrical insulator layer.
